(19) United States
(12) Patent Application Publication
(10) Pub. No.: US 2025/0239460 A1
(43) Pub. Date: Jul. 24, 2025

(54) METHOD OF ETCHING METAL OXIDE LAYER BY USING ATOMIC LAYER ETCHING

(71) Applicants: Samsung Electronics Co., Ltd., Suwon-si (KR); INDUSTRY-UNIVERSITY COOPERATION FOUNDATION HANYANG UNIVERSITY ERICA CAMPUS, Ansan-si (KR)

(72) Inventors: Kunsu PARK, Suwon-si (KR); Woohee KIM, Asan-si (KR); Jeonggyu SONG, Suwon-si (KR); Jeongbin LEE, Asan-si (KR); Wonsik CHOI, Suwon-si (KR); Beomseok KIM, Suwon-si (KR); Jungtae KIM, Asan-si (KR); Jooho LEE, Suwon-si (KR)

(73) Assignees: Samsung Electronics Co., Ltd., Suwon-si (KR); INDUSTRY-UNIVERSITY COOPERATION FOUNDATION HANYANG UNIVERSITY ERICA CAMPUS, Ansan-si (KR)

(21) Appl. No.: 18/980,788

(22) Filed: Dec. 13, 2024

(30) Foreign Application Priority Data
Jan. 18, 2024 (KR) 10-2024-0008286

(51) Int. Cl. H01L 21/311

(52) U.S. Cl. CPC H01L 21/31116

(57) ABSTRACT

A method of etching a metal oxide layer, by using atomic layer etching (ALE), may include providing a first precursor including a fluorinated material to a target surface of the metal oxide layer, forming a metal fluorinated layer by fluorinating the target surface of the metal oxide layer with the first precursor, providing a second precursor including a metal halogenated material to the metal fluorinated layer, and removing the metal fluorinated layer from the metal oxide layer by generating a volatile reactant from a reaction between the metal fluorinated layer and the metal halogenated material.

### CROSS-REFERENCE TO RELATED APPLICATION

This application is based on and claims priority under 35 U.S.C. § 119 to Korean Patent Application No. 10-2024-0008286, filed on Jan. 18, 2024, in the Korean Intellectual Property Office, the disclosure of which is incorporated by reference herein in its entirety.

### BACKGROUND

### 1. Field

The disclosure relates to a method of etching a metal oxide layer by using atomic layer etching.

### 2. Description of the Related Art

Atomic layer etching (ALE) is a process considered as one of the most prominent technologies of removing an atomic-scale thin layer of a material by using sequential self-limiting reaction and achieving required control of etch variability. ALE is similar to an atomic layer deposition (ALD) technology, except that removal occurs instead of deposition, which results in etching instead of deposition.

The most common ALE that has been reported to date is mainly implemented by using a plasma method and includes two stages of surface modification and removal. In other words, ALE of the prior art is a mechanism of forming a modified surface by using a precursor and then removing the modified surface by using a radicalized and ionized reaction gas generated from plasma. However, it is not possible to perfectly control damage to equipment and substrate defects caused by a plasma source.

Recently, ALE has been studied as a method of precisely adjusting a thickness of an insulating layer or a thin film.

### SUMMARY

Provided is a method of etching a metal oxide layer by using atomic layer etching.

Additional aspects will be set forth in part in the description which follows and, in part, will be apparent from the description, or may be learned by practice of the presented embodiments of the disclosure.

According to an embodiment of the disclosure, a method of etching a metal oxide layer, by using atomic layer etching (ALE), may include providing a first precursor including a fluorinated material to a target surface of the metal oxide layer; forming a metal fluorinated layer, the forming the metal fluorinated layer including fluorinating the target surface of the metal oxide layer with the first precursor; providing a second precursor including a metal halogenated material to the metal fluorinated layer; and removing the metal fluorinated layer from the metal oxide layer by generating a volatile reactant from a reaction between the metal fluorinated layer and the metal halogenated material.

In some embodiments, the first precursor may include one of molybdenum hexafluoride (MoF₆), hydrogen fluoride (HF), or HF-pyridine.

In some embodiments, the metal halogenated material may include one of titanium tetrachloride (TiCl₄), sulfuryl chloride (SO₂Cl₂), or dimethylaluminum chloride ((CH₃)₂AlCl (DMAC)).

In some embodiments, the second precursor may further include at least one of trimethylaluminum (Al(CH₃)₃ (TMA)), dimethylaluminum chloride ((CH₃)₂AlCl (DMAC)), acetylacetone (CH₃COCH₂COCH₃ (ACAC)), hexafluoroacetylacetone (CF₃COCH₂COCF₃ (HFAC)), silicon chloride (SiCl₄), or trimethylsilylchloride ((CH₃)₃SiCl).

In some embodiments, the method may further include purging the first precursor after the providing the first precursor or purging the second precursor after the providing the second precursor.

In some embodiments, a dielectric constant of the metal oxide layer may be 10 or greater.

In some embodiments, the metal oxide layer may include one of hafnium dioxide (HfO₂), zirconium dioxide (ZrO₂), or titanium dioxide (TiO₂).

In some embodiments, the method may further include etching the target surface of the metal oxide layer. The etching the target surface of the metal oxide layer may include repeating the providing the first precursor and the providing the second precursor for a plurality of cycles.

In some embodiments, the removing the metal fluorinated layer may be performed through a thermal process at a temperature of 150° C. to 300° C.

In some embodiments, the metal oxide layer may include at least one of hafnium dioxide (HfO₂), zirconium dioxide (ZrO₂), or titanium dioxide (TiO₂), and the second precursor may include at least one of titanium tetrachloride (TiCl₄), silicon chloride (SiCl₄), trimethylsilylchloride ((CH₃)₃SiCl), or sulfuryl chloride (SO₂Cl₂).

In some embodiments, a dielectric constant of the metal oxide layer may be 20 or greater.

In some embodiments, a bandgap of the metal oxide layer may be 3 to 8.

In some embodiments, an etch rate of the target surface may be determined according to a type of the first precursor.

In some embodiments, the second precursor may be in a gaseous state.

In some embodiments, a plasma gas may not be provided during the providing the first precursor and the providing the second precursor.

In some embodiments, during the etching the target surface of the metal oxide layer, an etch rate of the metal oxide layer may be 2 Å/cycle or less.

In some embodiments, a thickness of the target surface etched from the metal oxide layer may be 0.01 nm to 0.1 nm.

According to an embodiment of the disclosure, a method of etching a metal oxide layer, by using atomic layer etching (ALE), may include forming a metal oxide layer on a semiconductor layer; providing a first precursor including a fluorinated material to a target surface of the metal oxide layer; forming a metal fluorinated layer, the forming the metal fluorinate layer including fluorinating the target surface of the metal oxide layer with the first precursor; providing a second precursor including a metal halogenated material to the metal fluorinated layer; and removing the metal fluorinated layer from the metal oxide layer by generating a volatile reactant from a reaction between the metal fluorinated layer and the metal halogenated material.

In some embodiments, the metal oxide layer may include one of hafnium dioxide (HfO₂), zirconium dioxide (ZrO₂), or titanium dioxide (TiO₂).

### BRIEF DESCRIPTION OF THE DRAWINGS

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

The above and other aspects, features, and advantages of certain embodiments of the disclosure will be more apparent from the following description taken in conjunction with the accompanying drawings, in which:

FIG. 1 is a flowchart of a method of manufacturing a semiconductor device by using atomic layer etching (ALE), according to an embodiment;

FIGS. 2A to 2D are cross-sectional views according to a process order to describe a method of manufacturing a semiconductor device by using ALE, according to an embodiment;

FIG. 3 is a diagram for describing whether to inject a first precursor, a second precursor, a first purge gas, and a second purge gas for each unit cycle;

FIGS. 4A to 4E illustrate etch rates of metal oxide layers according to temperature when a first precursor and a second precursor are supplied;

FIGS. 5A to 5D illustrate other etch rates of metal oxide layers according to temperature when a first precursor and a second precursor are supplied;

FIGS. 6A and 6B are diagrams for describing self-limiting characteristics of a first precursor and a second precursor;

FIGS. 7A to 7C are diagrams for describing etch rate differences according to sequential supply of a first precursor and a second precursor;

FIGS. 8A and 8B are diagrams for describing etch rate differences according to a temperature and a type of a first precursor;

FIG. 9 is a diagram showing examples of a semiconductor layer, a metal oxide layer, and an electrode;

FIGS. 10A to 10C are diagrams for describing a change in a thickness of a metal oxide layer according to ALE;

FIG. 11 is a schematic diagram of a field effect transistor according to an embodiment;

FIG. 12 illustrates an electronic device according to an embodiment;

FIG. 13 is a cross-sectional view of the electronic device taken along a line A-A′ of FIG. 12;

FIG. 14 is a conceptual diagram schematically showing a device architecture applicable to a device, according to an embodiment; and

FIG. 15 is a conceptual diagram schematically showing a device architecture applicable to a device, according to an embodiment.

### DETAILED DESCRIPTION

Hereinafter, embodiments will be described in detail with reference to accompanying drawings. In the drawings, like reference numerals denote like elements and the sizes of the elements may be exaggerated for clarity and convenience of description. Embodiments described below are only examples and various modifications may be made from such embodiments.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When an element is described to be “on” or “above” another element, the element may contact and be directly on or below, or directly at the left or right of the other element or may be on or below, or directly at the left or right of the other element without contacting the other element. An expression used in the singular encompasses the expression in the plural, unless it has a clearly different meaning in the context. In addition, when a part “comprises (includes)” a certain element, the part may further include another element instead of excluding the other element, unless otherwise stated.

The use of the term “the” and similar indicative terms may correspond to both the singular and the plural. Operations constituting a method may be performed in an appropriate order and is not necessarily limited by a state order unless otherwise stated or an order is clearly stated.

In addition, terms such as “unit”, “-or/-er”, and “module” described in the specification denote a unit that processes at least one function or operation, which may be implemented in hardware or software, or implemented in a combination of hardware and software.

Connection or connection members of lines between components shown in the drawings exemplarily represent functional connections and/or physical or circuit connections, and in an actual apparatus, may be replaced or may be implemented as various additional functional connections, physical connections, or circuit connections.

The use of all examples or example terms is merely for describing the technical ideas in detail, and the scope of the disclosure is not limited by the examples or example terms unless limited by the claims.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

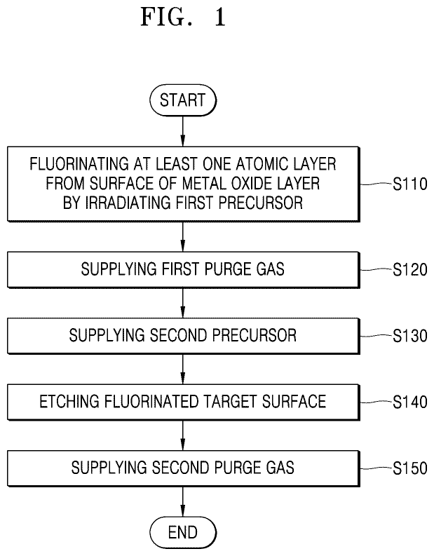

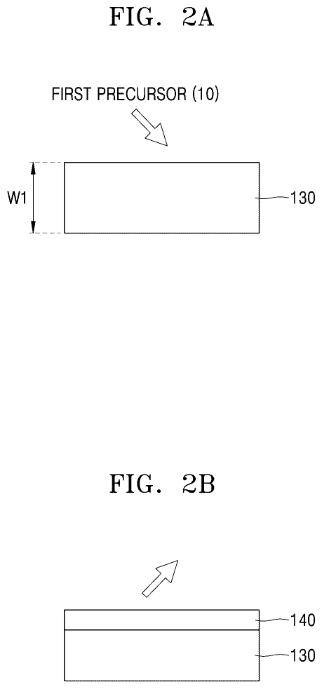

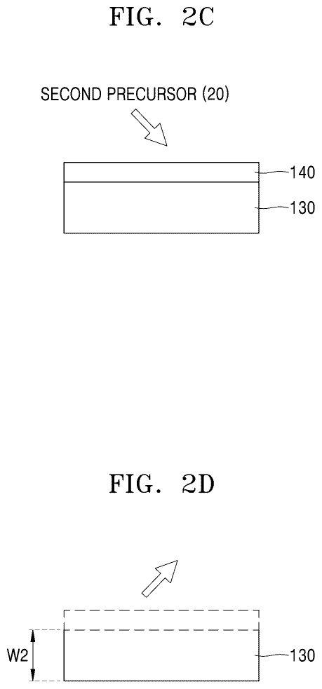

FIG. 1 is a flowchart of a method of etching a metal oxide layer by using atomic layer etching (ALE), according to an embodiment. FIGS. 2A to 2D are cross-sectional views according to a process order to describe a method of manufacturing a semiconductor device by using ALE, according to an embodiment.

Referring to FIGS. 1 and 2A to 2D, the method of etching a metal oxide layer by using ALE, according to the present embodiment, may first include, in operation S110, fluorinating at least one atomic layer from a surface of a metal oxide layer 130 formed on a substrate.

To perform the fluorinating (operation S110), the metal oxide layer 130 may be provided first as shown in FIG. 2A. The metal oxide layer 130 may include a metal or a metal compound. Examples of the metal of the metal oxide layer 130 may include at least one of aluminum (AI), zirconium (Zr), iron (Fe), manganese (Mn), magnesium (Mg), chromium (Cr), gallium (Ga), zinc (Zn), lead (Pb), germanium (Ge), tin (Sn), copper (Cu), titanium (Ti), tantalum (Ta), tungsten (W), molybdenum (Mo), ruthenium (Ru), rhodium (Rh), cobalt (Co), niobium (Nb), hafnium (Hf), nickel (Ni), platinum (Pt), ytterbium (Yb), terbium (Tb), dysprosium (Dy), erbium (Er), and palladium (Pd). Examples of the metal compound of the metal oxide layer 130 may include at least one of hafnium dioxide (HfO₂), zirconium dioxide (ZrO₂), titanium dioxide (TiO₂), silicon chloride (SiCl₄), carbon-doped silicon oxide (SiOCH), hafnium silicon oxynitride (HfSiON), hafnium silicon oxide (HfSiOx), lanthanum aluminum oxide (LaAlOx), lanthanum oxide (La₂O₃), and lanthanum silicon oxide (LaSiOx), wherein x is a natural number. However, the metal oxide layer 130 is not limited by the above examples. The metal oxide layer 130 may have a first thickness W1. The metal oxide layer 130 is not necessarily limited to a metal oxide. For example, the metal oxide layer 130 may be applied to a metal compound that does not include oxygen.

The metal oxide layer 130 may be provided on a device framework (not shown). The device framework may include various device structures formed in a front-end of the line (FEOL). For example, the device framework may have a structure of a dynamic random-access memory (DRAM) cell transistor, a three-dimensional (3D) NAND flash memory, a fin field-effect transistor (FinFET), a multi-bridge channel field-effect transistor (MBCFET), a capacitor, and a transistor. In other words, depending on which structure the device framework includes, a structure may include various devices.

An insertion layer (not shown) formed adjacent to the metal oxide layer 130 may be separately provided.

The metal oxide layer 130 may correspond to a dielectric layer 300 of a capacitor included in DRAM or may correspond to an insertion layer included inside, on, or below the dielectric layer 300.

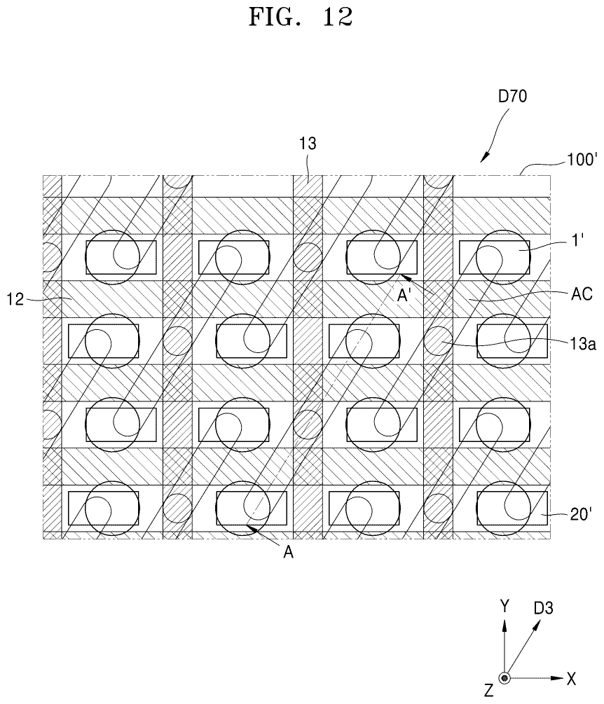

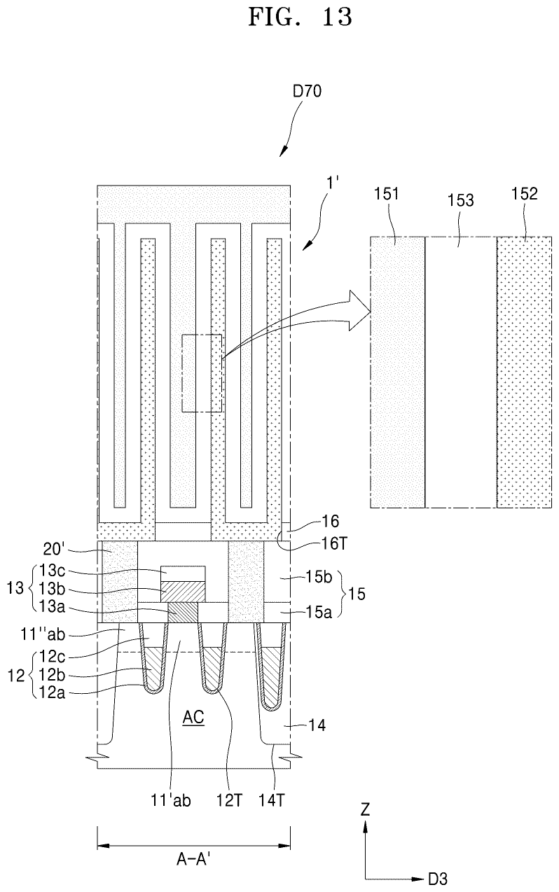

The dielectric layer 300 may be a component of the capacitor described in detail with reference to FIGS. 12 and 13, together with a lower electrode and an upper electrode. When the dielectric layer 300 includes one of HfO₂, ZrO₂, and TiO₂, a dielectric constant of the dielectric layer 300 may be about 20 or greater. However, the dielectric layer 300 is not necessarily limited to such a material and may further include a high dielectric (high-k) material, a high-k oxide, or a high-k nitride.

The insertion layer may include a material with a high bandgap, and the insertion layer may prevent a leakage current by including the material with a high bandgap. For example, the insertion layer may include one of aluminum oxide (Al₂O₃) and tin dioxide (SnO₂), but is not necessarily limited thereto and may further include a material with a high bandgap. Here, a bandgap denotes a minimum amount of energy required for one electron to escape from a bound state, and when bandgap energy is satisfied, the electron is excited and becomes free and thus may participate in conduction. A material with a high bandgap requires more energy for an electron to be excited into a free state.

When the insertion layer provided as a component of the capacitor includes Al₂O₃, a bandgap of the insertion layer may be about 6 or greater, and when the insertion layer includes SnO₂, the bandgap of the insertion layer may be about 4 or greater. The bandgap of the insertion layer may be determined according to a material included in the insertion layer, and a leakage current may be prevented when the insertion layer includes a material with a high bandgap. An effect of the insulation layer is not limited thereto and may vary.

The insertion layer may be formed according to ALE according to an embodiment. The ALE may be the same as the etching of the metal oxide layer 130 described in detail with reference to FIG. 1. The ALE may be performed on the insertion layer instead of the metal oxide layer 130. The insertion layer manufactured by using an ALE method according to an embodiment may be provided inside, above, or below the dielectric layer 300 of the capacitor, as described above.

Referring to FIGS. 2A to 2B, the fluorinating (operation S110) may indicate a process of supplying a first precursor 10 on the metal oxide layer 130 to convert a target surface of the metal oxide layer 130 or a portion of a top of the metal oxide layer 130 into a metal fluorinated layer 140. The first precursor 10 may include at least one of a hydrogen fluoride gas, a fluorocarbon gas, a nitrogen-containing gas, a sulfur-containing gas, and a chlorine-containing gas. For example, the first precursor 10 may include molybdenum hexafluoride (MoF₆), hydrogen fluoride (HF), HF-pyridine, carbon fluoride (CxFy), hydrofluorocarbon (CHxFy), chlorine (Cl₂), boron trichloride (BCl₃), hydrogen bromide (HBr), nitrogen trifluoride (NF₃), and sulfur hexafluoride (SF₆), wherein x and y are natural numbers. The target surface may include fluorinating at least one atomic layer among the metal oxide layer 130, according to the fluorinating (operation S110). The metal fluorinated layer 140 may include a metal fluoride. For example, the metal fluorinated layer 140 may include a material such as MoF₆ and Mo₂CFx, wherein x is a natural number. The metal fluorinated layer 140 may include a material the same as that included in the metal oxide layer 130. A method of the prior art and a method according to an embodiment, which are related to the fluorinating (operation S110) will be described below.

In the prior art, a specific precursor in a state of a plasma gas is supplied to a substrate or target surface. Plasma may include various components, such as radicals, electrons, ions, ultraviolet rays, and neutrons. At least one of such components may be used during etching. When plasma is used during etching, radicals may be used to etch an etching target isotropically and ions may be used to etch an etching target anisotropically. However, when a precursor is supplied or injected in a state of a plasma gas, thin-film uniformity and thin-film conformality of a target surface are decreased.

Unlike the prior art, providing or supplying of the first precursor 10, according to an embodiment, does not include supplying of a plasma gas, and the first precursor 10 may be supplied to a target surface through a thermal process at a certain temperature. In detail, after providing or injecting of the first precursor 10, self-limiting reaction (e.g., self-limited fluorination) may occur on the target surface. Accordingly, the target surface may be modified to a state in which ligand-exchange and volatilization reactions with respect to a second precursor 20, which will be described later, occur more thermodynamically. Then, thin-film uniformity and thin-film conformality, which are higher than those of the prior art, may be obtained by selectively etching only a fluorinated target surface formed on the modified target surface. In more detail, the target surface may be etched when volatile byproducts generated through the ligand-exchange are evaporated.

The metal oxide layer 130 may be crystalized through a thermal process before the fluorinating (operation S110). For example, the metal oxide layer 130 may be crystalized at a temperature of 400° C. or lower. Obviously, a crystallization temperature is not limited to such a value.

After the fluorinating (operation S110), a first purge gas may be supplied in operation S120. A residual gas, byproducts, and the like are removed by purging the inside of etching equipment (e.g., a chamber) where ALE is performed, through the first purge gas. The first purge gas may include an inert gas, for example, dinitrogen (N₂), neon (Ne), argon (Ar), krypton (Kr), xenon (Xe), or radon (Rn). However, the first purge gas is not limited thereto.

After the first purge gas is supplied (operation S120), the second precursor 20 may be supplied or injected in operation S130. The second precursor 20 may include a metal halide. The metal halide may include at least one of titanium tetrachloride (TiCl₄), sulfuryl chloride (SO₂Cl₂), trimethylaluminum (Al(CH₃)₃ (TMA), and dimethylaluminum chloride ((CH₃)₂AlCl (DMAC). The second precursor 20 may further include one of acetylacetone (CH₃COCH₂COCH₃ (ACAC)), hexafluoroacetylacetone (CF₃COCH₂COCF₃ (HFAC)), silicon chloride (SiCl₄), and trimethylsilylchloride ((CH₃)₃SiCl), but is not limited thereto.

Referring to FIGS. 1 and 2C, etching (operation S140) may be performed. As described above, the ligand-exchange may occur between the second precursor 20 and a portion of the atomic layer of the target surface of the metal oxide layer 130, the volatile byproducts are generated according to the ligand-exchange, and the generated volatile byproducts are evaporated from the target surface. As a result, the metal fluorinated layer 140 may be removed. Thus, the target surface may be etched from the metal oxide layer 130.

After the etching (operation S140), a second purge gas may be supplied in operation S150. The residual gas, byproducts, and the like are removed by purging the inside of the etching equipment where ALE is performed, through the second purge gas. The second purge gas may include an inert gas, for example, N₂, Ne, Ar, Kr, Xe, or Rn.

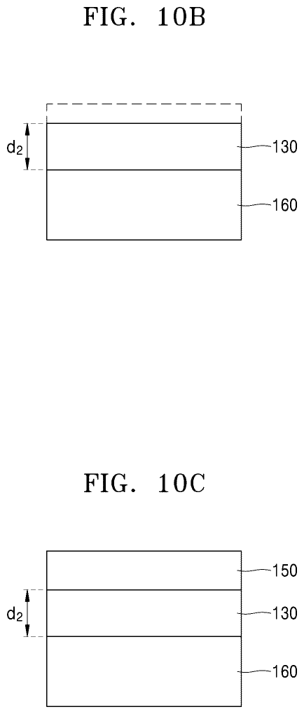

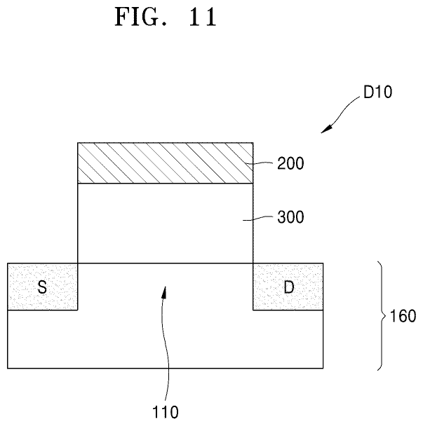

Then, the second purge gas is discharged as an exhaust gas to complete the method of etching a metal oxide layer by using ALE and remove a portion of the top of the metal oxide layer 130. A thickness of the metal oxide layer 130 may be precisely adjusted in a level of an atomic size by adjusting supply amounts, temperatures, and times of the first precursor 10 and the second precursor 20. Referring to FIG. 2D, after the portion of the top of the metal oxide layer 130 is removed, the metal oxide layer 130 may have a second thickness W2. The second thickness W2 may correspond to a thickness d2 shown in FIG. 10B and may be less than the first thickness W1.

The target surface may be removed after the etching (operation S140) is performed. According to an embodiment, after the etching (operation S140) is performed, a portion of the target surface may remain. Accordingly, the etching of the metal oxide layer 130 may be completed and in addition, a semiconductor device including the metal oxide layer 130 may be manufactured.

Thin-film uniformity and surface roughness of a metal may be factors affecting carrier transfer in the semiconductor device of a nano unit, such as DRAM, 3D NAND flash memory, FinFET, or MBCFET. When the surface roughness is high, interface resistance is increased, and thus, an electric characteristic of the semiconductor device may deteriorate.

The method of etching a metal oxide layer by using ALE, according to embodiments, may separate the fluorinating (operation S110) and the etching (operation S140). Here, the thickness of the metal oxide layer 130 may be precisely adjusted in a level of an atomic size by adjusting the supply amounts, temperatures, and times of the first precursor 10 and the second precursor 20. In this regard, the thin-film uniformity and the surface roughness of the metal oxide layer 130 may be improved.

Thicknesses of the target surface included in the metal oxide layer 130 and the metal fluorinated layer 140 provided in the metal oxide layer 130 may be 0.01 nm or greater, but are not limited thereto and may vary according to a type of the metal oxide layer 130 and a composition of materials included in the metal oxide layer 130.

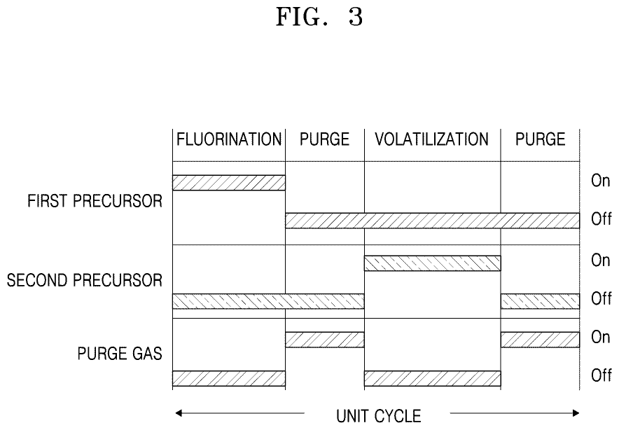

FIG. 3 is a diagram for describing whether to inject the first precursor 10, the second precursor 20, the first purge gas, and the second purge gas for each unit cycle, in the method of etching the metal oxide layer 130.

Referring to FIG. 3, the first precursor 10 may be injected and the target surface of the metal oxide layer 130 may be fluorinated (see FIGS. 2A and 2B) in a first stage of the unit cycle of the method. After the first precursor 10 is fluorinated, the injecting of the first precursor 10 may be turned off and a specific purge gas may be injected, thereby entering a purge gas on stage. After the purge gas is injected, the second precursor 20 is injected (see FIG. 2C) and reacts with the target surface and the metal fluorinated layer 140 to generate the volatile byproducts, and a volatilization stage of the second precursor 20 may be turned on. After the volatilization stage of the second precursor 20 is ended, the purge gas on stage may be started.

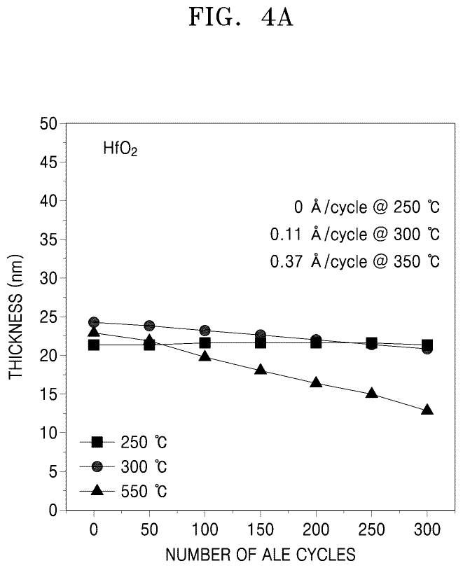

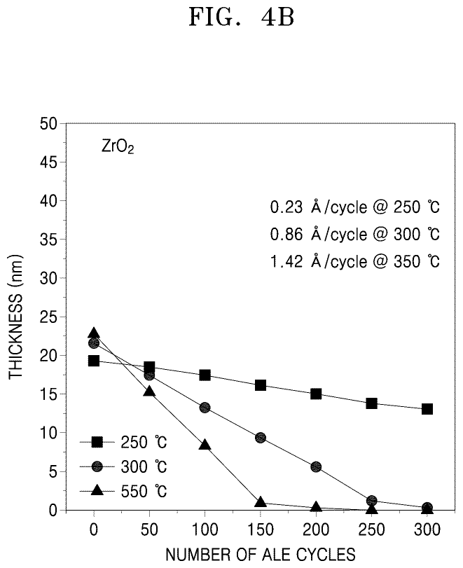

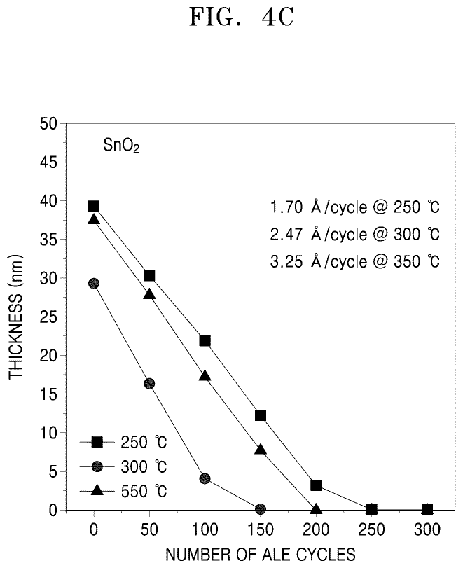

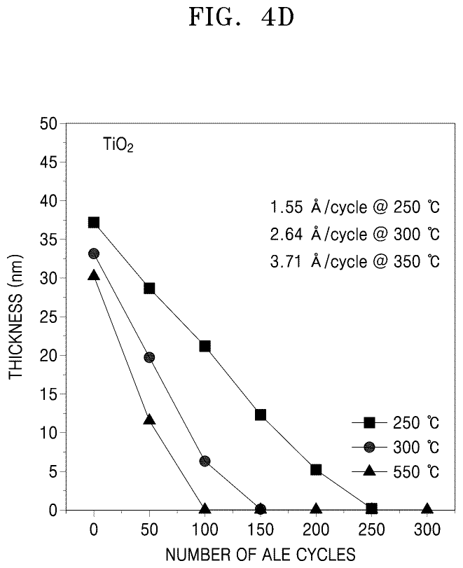

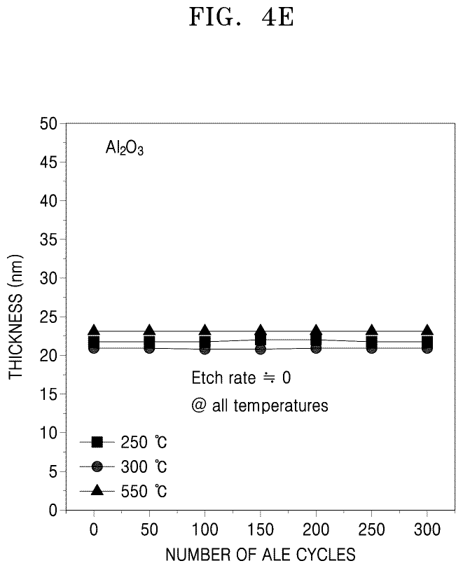

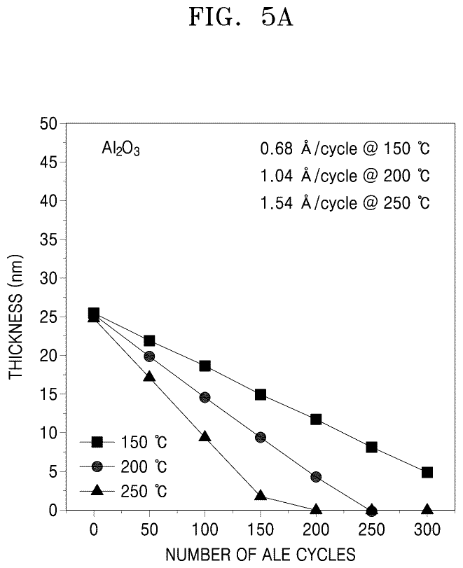

FIGS. 4A to 4E illustrate etch rates of metal oxide layers or insertion layers according to temperature when a first precursor and a second precursor are supplied.

Referring to FIGS. 4A to 4E, FIGS. 4A to 4E illustrate the etch rates of the metal oxide layers or insertion layers according to temperature when MoF₆ is supplied as the first precursor and TiCl₄ is supplied as the second precursor. An x-axis denotes the number of ALE cycles and a y-axis denotes a thickness of the metal oxide layer 130.

FIG. 4A illustrates amounts of reduced thicknesses of the metal oxide layer 130 obtained as a cycle of an etching process is increased when temperatures of the etching process of the metal oxide layer 130 are 250° C., 300° C., and 350° C., in a case where the metal oxide layer 130 is HfO₂, the first precursor is MoF₆, and the second precursor is TiCl₄. The thickness of the metal oxide layer 130 is less when the etching process is performed at 350° C. than when the etching process is performed at 250° C. In detail, when the etching process is performed at 250° C., the thickness of the metal oxide layer 130 (HfO₂) etched per unit etching cycle may be 0 Å, when the etching process is performed at 300° C., the thickness of the metal oxide layer 130 (HfO₂) etched per unit etching cycle may be 0.11 Å, and when the etching process is performed at 350° C., the thickness of the metal oxide layer 130 (HfO₂) etched per unit etching cycle may be 0.37 Å. However, the disclosure is not limited by such etch rates and the etch rate may change according to another factor affecting the etch rate.

FIG. 4B illustrates the amounts of reduced thicknesses of the metal oxide layer 130 obtained as the cycle of the etching process is increased when the temperatures of the etching process of the metal oxide layer 130 are 250° C., 300° C., and 350° C., in a case where the metal oxide layer 130 is ZrO₂, the first precursor is MoF₆, and the second precursor is TiCl₄. As in HfO₂, when the metal oxide layer 130 is ZrO₂, the thickness of the metal oxide layer 130 is less when the etching process is performed at 350° C. than when the etching process is performed at 250° C. In detail, when the etching process is performed at 250° C., the thickness of the metal oxide layer 130 (ZrO₂) etched per unit etching cycle may be 0.23 Å, when the etching process is performed at 300° C., the thickness of the metal oxide layer 130 etched per unit etching cycle may be 0.86 Å, and when the etching process is performed at 350° C., the thickness of the metal oxide layer 130 etched per unit etching cycle may be 1.42 Å. However, the disclosure is not limited by such etch rates and the etch rate may change according to another factor affecting the etch rate.

FIG. 4C illustrates amounts of reduced thicknesses of the insertion layer obtained as a cycle of an etching process is increased when temperatures of the etching process of the insertion layer (SnO₂) are 250° C., 300° C., and 350° C., in a case where the insertion layer is SnO₂, the first precursor is MoF₆, and the second precursor is TiCl₄. As in HfO₂ and ZrO₂, when the insertion layer is SnO₂, the thickness of the insertion layer is less when the etching process is performed at 350° C. than when the etching process is performed at 250° C. In detail, when the etching process is performed at 250° C., the thickness of the insertion layer (SnO₂) etched per unit etching cycle may be 1.70 Å, when the etching process is performed at 300° C., the thickness of the insertion layer (SnO₂) etched per unit etching cycle may be 2.47 Å, and when the etching process is performed at 350° C., the thickness of the insertion layer (SnO₂) etched per unit etching cycle may be 3.25 Å. However, the disclosure is not limited by such etch rates and the etch rate may change according to another factor affecting the etch rate.

FIG. 4D illustrates the amounts of reduced thicknesses of the metal oxide layer 130 (TiO₂) obtained as the cycle of the etching process is increased when the temperatures of the etching process of the metal oxide layer 130 (TiO₂) are 250° C., 300° C., and 350° C., in a case where the metal oxide layer 130 is TiO₂, the first precursor is MoF₆, and the second precursor is TiCl₄. As in HfO₂ and ZrO₂, when the metal oxide layer 130 is TiO₂, the thickness of the metal oxide layer 130 is less when the etching process is performed at 350° C. than when the etching process is performed at 250° C. In detail, when the etching process is performed at 250° C., the thickness of the metal oxide layer 130 (TiO₂) etched per unit etching cycle may be 1.55 Å, when the etching process is performed at 300° C., the thickness of the metal oxide layer 130 (TiO₂) etched per unit etching cycle may be 2.64 Å, and when the etching process is performed at 350° C., the thickness of the metal oxide layer 130 (TiO₂) etched per unit etching cycle may be 3.71 Å. However, the disclosure is not limited by such etch rates and the etch rate may change according to another factor affecting the etch rate.

FIG. 4E illustrates the amounts of reduced thicknesses of the insertion layer (Al₂O₃) obtained as the cycle of the etching process is increased when temperatures of the etching process of the insertion layer (Al₂O₃) are 250° C., 300° C., and 350° C., in a case where the insertion layer is Al₂O₃, the first precursor is MoF₆, and the second precursor is TiCl₄. As shown in FIG. 4E, the insertion layer is not etched regardless of a temperature of the etching process and supply amounts of the first precursor and second precursor. To perform ALE on a specific metal oxide layer, a specific first precursor and a specific second precursor for etching the specific metal oxide layer need to be supplied.

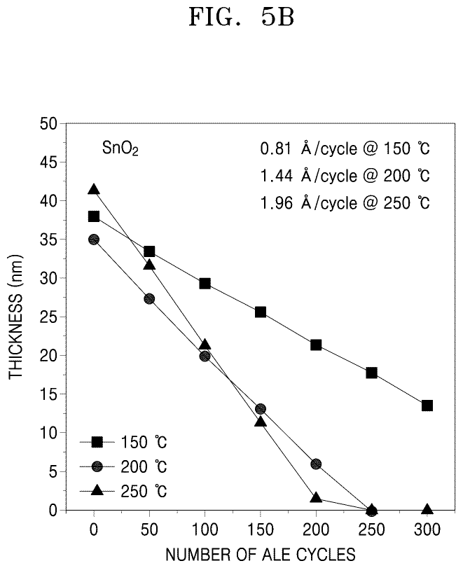

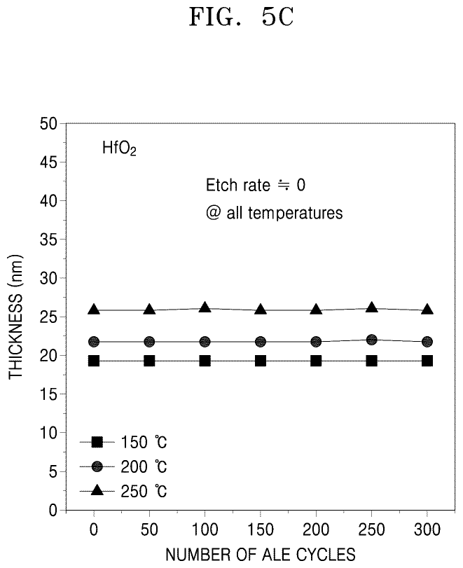

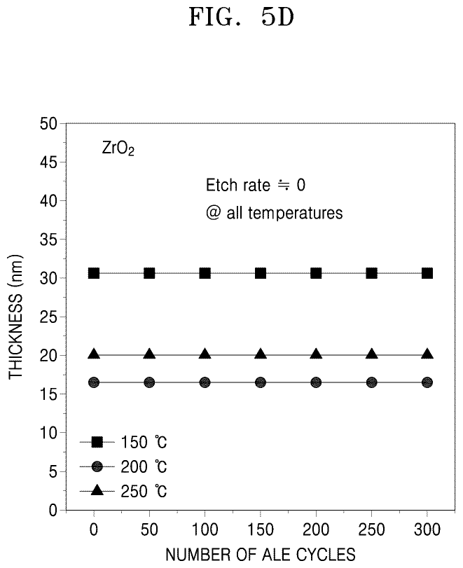

FIGS. 5A to 5D illustrate other etch rates of metal oxide layers according to temperature when a first precursor and a second precursor are supplied.

FIG. 5A illustrates the amounts of reduced thicknesses of the insertion layer obtained as the cycle of the etching process is increased when the temperatures of the etching process of the insertion layer are 150° C., 200° C., and 250° C., in a case where the insertion layer is Al₂O₃, the first precursor is MoF₆, and the second precursor is acetylacetone (CH₃COCH₂COCH₃ (ACAC)). When the insertion layer is Al₂O₃, the thickness of the insertion layer is less when the etching process is performed at 250° C. than when the etching process is performed at 150° C. In detail, when the etching process is performed at 150° C., the thickness of the insertion layer etched per unit etching cycle may be 0.68 Å, when the etching process is performed at 200° C., the thickness of the insertion layer etched per unit etching cycle may be 1.04 Å, and when the etching process is performed at 250° C., the thickness of the insertion layer etched per unit etching cycle may be 1.54 Å. However, the disclosure is not limited by such etch rates and the etch rate may change according to another factor affecting the etch rate.

FIG. 5B illustrates the amounts of reduced thicknesses of the insertion layer obtained as the cycle of the etching process is increased when the temperatures of the etching process of the insertion layer are 150° C., 200° C., and 250° C., in a case where the insertion layer is SnO₂, the first precursor is MoF₆, and the second precursor is acetylacetone (CH₃COCH₂COCH₃ (ACAC)). As in a case where the insertion layer is Al₂O₃, when the insertion layer is SnO₂, the thickness of the insertion layer is less when the etching process is performed at 250° C. than when the etching process is performed at 150° C. In detail, when the etching process is performed at 150° C., the thickness of the insertion layer (SnO₂) etched per unit etching cycle may be 0.81 Å, when the etching process is performed at 200° C., the thickness of the insertion layer (SnO₂) etched per unit etching cycle may be 1.44 Å, and when the etching process is performed at 250° C., the thickness of the insertion layer (SnO₂) etched per unit etching cycle may be 1.96 Å. However, the disclosure is not limited by such etch rates and the etch rate may change according to another factor affecting the etch rate.

FIGS. 5C and 5D illustrate the amounts of reduced thicknesses of the metal oxide layer 130 (HfO₂ or ZrO₂) obtained as the cycle of the etching process is increased when the temperatures of the etching process of the metal oxide layer 130 (HfO₂ or ZrO₂) are 150° C., 200° C., and 250° C., in a case where the metal oxide layer 130 is HfO₂ or ZrO₂, the first precursor is MoF₆, and the second precursor is acetylacetone (CH₃COCH₂COCH₃ (ACAC)). As shown in FIGS. 5C and 5D, the metal oxide layer 130 (HfO₂ or ZrO₂) is not etched regardless of a temperature of the etching process and supply amounts of the first precursor and second precursor. To perform ALE on a specific metal oxide layer, a specific first precursor and a specific second precursor for etching the specific metal oxide layer need to be supplied.

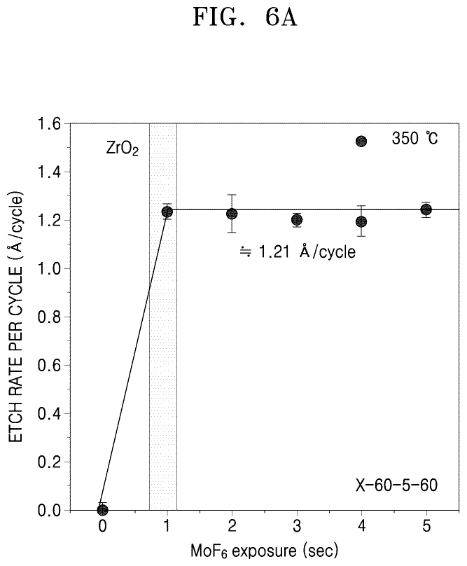

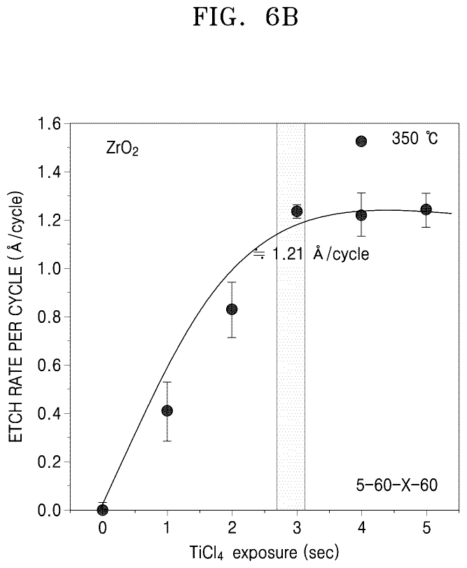

FIGS. 6A and 6B are diagrams for describing self-limiting characteristics of a first precursor and a second precursor.

FIGS. 6A and 6B illustrate etch rates of metal oxide layers, proportional to exposure times or exposure amounts of the first precursor and the second precursor, when the first precursor is MoF₆, the second precursor is TiCl₄, and the metal oxide layer is ZrO₂.

When the exposure times or exposure amounts of the first precursor and the second precursor increase, the etch rates per unit cycle illustrated in a y-axis may increase. However, when the exposure times or the exposure amounts of the first precursor and the second precursor increase by a certain range or greater, the etch rates per unit cycle illustrated in the y-axis may not increase. Such a characteristic of ALE may be referred to as a self-limiting reaction.

For example, when a processing temperature of ALE is 350° C., the metal oxide layer is ZrO₂, and the first precursor is MoF₆, the etch rate of the metal oxide layer per unit cycle may barely increase in 1.21 Å within a range where the exposure time of the first precursor is about 1.1 seconds or greater. Such a characteristic may be referred to as a self-limiting reaction.

Such a self-limiting characteristic of ALE may also be applied to when the first precursor is MoF₆, the second precursor is acetylacetone (CH₃COCH₂COCH₃ (ACAC)), the metal oxide layer is Al₂O₃ or SnO₂, and the processing temperature of the ALE is 250° C.

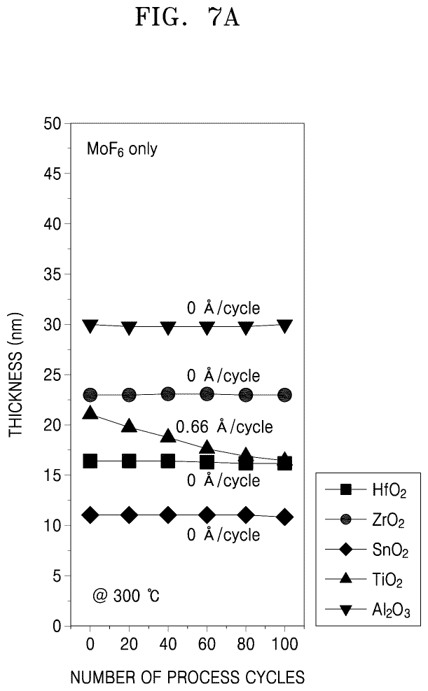

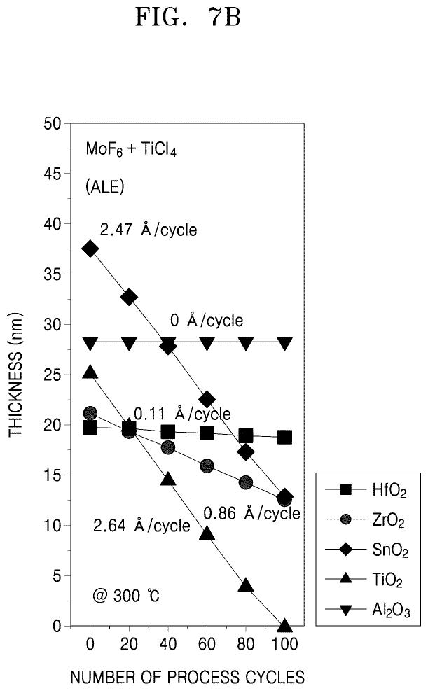

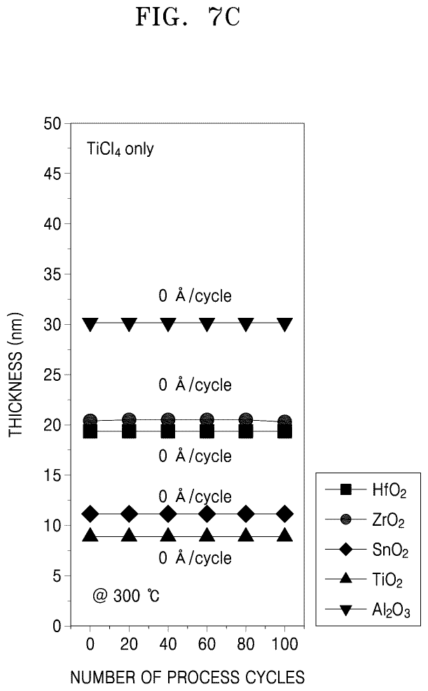

FIGS. 7A to 7C are diagrams for describing etch rate differences according to sequential supply of a first precursor and a second precursor.

Referring to FIGS. 7A to 7C, etch rates of a metal oxide layer per unit cycle of ALE when only a first precursor is supplied, when only a second precursor is supplied, and when both the first precursor and the second precursor are supplied may be compared.

In a case where the first precursor is MoF₆ and the second precursor is TiCl₄, the etch rate of the metal oxide layer per unit cycle of ALE when only the first precursor is supplied and the etch rate of the metal oxide layer per unit cycle of the ALE when only the second precursor is supplied may be mostly 0 or have a very low value regardless of a type of the metal oxide layer.

On the other hand, when both the first precursor and the second precursor are supplied, the etch rate of the metal oxide layer per unit cycle of the ALE may have a high value compared to when only the first precursor or the second precursor is supplied, except for a case where the metal oxide layer is Al₂O₃.

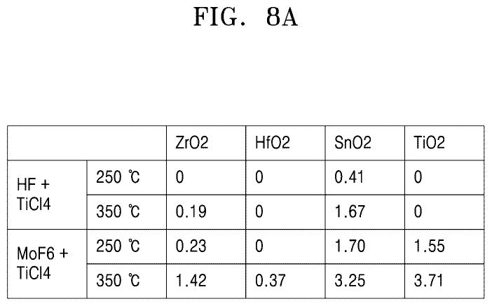

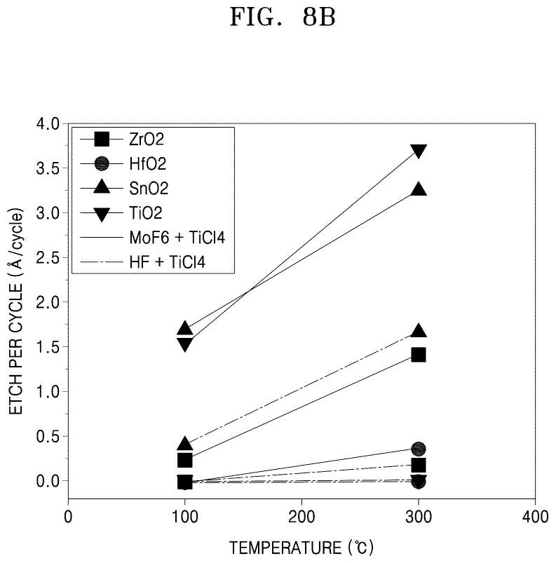

FIGS. 8A and 8B are diagrams for describing etch rate differences according to a temperature and a type of a first precursor.

FIG. 8A illustrates the etch rate differences according to a type of the metal oxide layer 130 when a second precursor is TiCl and the first precursor is HF or MoF₆.

In detail, when the first precursor is HF, the second precursor is TiCl₄, and the metal oxide layer 130 is HfO₂ or TiO₂, a target surface of the metal oxide layer 130 may not be etched regardless of a processing temperature of ALE. On the other hand, when the first precursor is HF or MoF₆, the second precursor is TiCl₄, and the metal oxide layer 130 is ZrO₂ or SnO₂, an etch rate may be higher when a temperature of ALE is 350° C. than when the temperature of ALE is 250° C.

Referring to FIG. 8B, an etch rate per unit cycle increases as a temperature of ALE increases when the first precursor is HF or MoF₆, the second precursor is TiCl₄, and the metal oxide layer 130 is ZrO₂ or SnO₂, except for a case where the first precursor is HF, the second precursor is TiCl₄, and the metal oxide layer 130 is HfO₂ or TiO₂, as described with reference to Table of FIG. 8A. The etch rate per unit cycle of ALE may be determined according to configurations or types of the first precursor, the second precursor, and the metal oxide layer 130.

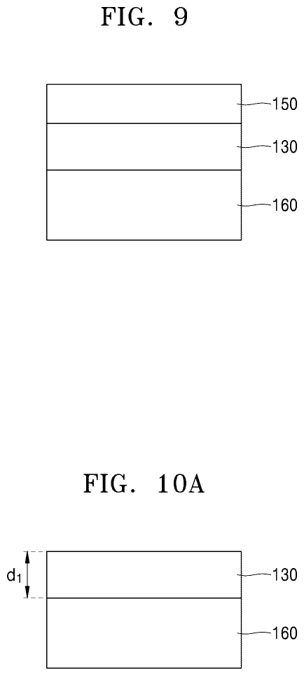

FIG. 9 is a diagram of a semiconductor device including the metal oxide layer 130, according to an embodiment.

Referring to FIG. 9, the metal oxide layer 130 may be provided on a semiconductor layer 160 and an electrode 150 may be provided on the metal oxide layer 130. The semiconductor layer 160 may include an IV group semiconductor, a two-dimensional (2D) semiconductor, or an oxide semiconductor. For example, the semiconductor layer 160 may include Si, Ge, SiGe, MoS₂, WSe₂, graphene, IGZO, IWO, or ZnSnO. In addition, the semiconductor layer 160 may include a III-V group compound semiconductor or a II-VI group compound semiconductor.

The electrode 150 may be arranged on the semiconductor layer 160. The electrode 150 may include at least one material selected from a metal, a metal nitride, a metal carbide, polysilicon, and a combination thereof.

FIGS. 10A to 10C are reference diagrams for describing a method of manufacturing the semiconductor device.

The method of FIGS. 10A to 10C is the same as the method of etching the metal oxide layer 130 described above with reference to FIGS. 2A to 2D. In detail, an existing thickness d1 of the metal oxide layer 130 may change to the new thickness d2 by providing a first precursor including a fluorinated material to a target surface of the metal oxide layer 130, forming a metal fluorinated layer by fluorinating the target surface of the metal oxide layer 130 with the first precursor, providing a second precursor including a metal halogenated material to the metal fluorinated layer, and removing the metal fluorinated layer from the metal oxide layer 130 by using a volatile reactant generated after a reaction between the metal fluorinated layer and the metal halogenated material. The new thickness d2 may have a lower value than the existing thickness d1, and at this time, the new thickness d2 may be about 0.01 nm to about 0.5 nm, but is not necessarily limited thereto.

The electrode 150 may be disposed on the metal oxide layer 130 having the new thickness d2 after ALE is completed.

FIG. 11 is a schematic diagram of a field effect transistor D10 that is an example of a semiconductor device, according to an embodiment.

The field effect transistor D10 shown in FIG. 11 may be manufactured by using the method of etching a metal oxide layer by using ALE, which is described above with reference to FIGS. 1 to 2D. Referring to FIG. 11, the field effect transistor D10 includes a substrate including a source S and a drain D, a gate electrode 200 disposed on the substrate, and the dielectric layer 300 arranged between the substrate and the gate electrode 200. Here, the dielectric layer 300 may correspond to the dielectric layer 300 described above.

The substrate may include a semiconductor material. For example, the substrate may include Si, Ge, SiGe, or III-V group semiconductor, and may be modified in various forms, such as silicon on insulator (SOI).

The substrate may include the source S and the drain D, and include a channel 110 electrically connected to the source S and the drain D. The source S may be electrically connected to or in contact with one end portion of the channel 110, and the drain D may be electrically connected to or in contact with another end portion of the channel 110.

Referring to FIG. 11, the channel 110 may be defined as a region of the substrate, between the source S and the drain D. The source S and the drain D may be formed by injecting impurities into different regions of the substrate, and in this case, the source S, the channel 110, and the drain D may correspond to the semiconductor layer 160 of FIGS. 9 and 10A.

Also, referring to FIG. 11, the channel 110 may be realized as a material layer (thin film) separate from a region of the substrate. A material of the channel 110 may vary. For example, the channel 110 may include not only a semiconductor material, such as Si, Ge, SiGe, or a III-V group semiconductor, but also one or more of an oxide semiconductor, a nitride semiconductor, an oxynitride semiconductor, a 2D material, a quantum dot, an organic semiconductor, and a combination thereof. For example, the oxide semiconductor may include InGaZnO, the 2D material may include transition metal dichalcogenide (TMD), or graphene, and the quantum dot may include a colloidal quantum dot (QD) or a nanocrystal structure. The source S and the drain D may be formed of a conductive material, and for example, may independently include a metal, a metal compound, or conductive polymer.

The gate electrode 200 may be spaced apart from the substrate, on the substrate, and may face the channel 110.

The gate electrode 200 may have conductivity of about 1 Mohm/square or less. The gate electrode 200 may include at least one material selected from a metal, a metal nitride, a metal carbide, polysilicon, and a combination thereof. For example, the metal may include aluminum (Al), tungsten (W), molybdenum (Mo), titanium (Ti), or tantalum (Ta), the metal nitride may include a titanium nitride (TiN) film or a tantalum nitride (TaN) film, and the metal carbide may be an Al or Si-doped (or contained) metal carbide, specifically, TiAlC, TaAlC, TiSiC, or TaSiC. The gate electrode 200 may have a structure in which a plurality of materials are stacked on each other. For example, the gate electrode 200 may have, for example, a stack structure of metal nitride layer/metal layer, such as TiN/AI, or a stack structure of metal nitride/metal carbide layer/metal layer, such as TIN/TiAlC/W. The gate electrode 200 may include TiN or Mo and above examples may be variously modified. Although the gate electrode 200 is not illustrated in FIGS. 9 and 10A, the gate electrode 200 may be included in a general structure of the field effect transistor D10, and thus, the field effect transistor D10 may include the metal oxide layer 130 that may be manufactured according to FIGS. 1, 9, and 10A.

The dielectric layer 300 may be arranged between the substrate and the gate electrode 200. The dielectric layer 300 may be formed of a metal oxide. The dielectric layer 300 may be formed by using the method of etching a metal oxide layer, according to an embodiment. In this case, the dielectric layer 300 may correspond to the metal oxide layer 130 of FIGS. 9 and 10A. Also, the dielectric layer 300 may include a high-k material. For example, the dielectric layer 300 may include one of HfO₂, ZrO₂, and TiO₂. A dielectric constant of a material included in the dielectric layer 300 may be 10 or greater (e.g., 10 to 110), but is not necessarily limited thereto.

The dielectric layer 300 may include a paraelectric material or a high-k material and may have a dielectric constant of about 20 to about 100.

A thickness of the dielectric layer 300 may be 2 nm or greater, 3 nm or greater, 4 nm or greater, 10 nm or less, or 5 nm or less. For example, a DRAM type semiconductor device may require a ferroelectric layer with a thickness of about 5 nm and a NAND type semiconductor device may require a dielectric layer with a thickness of about 10 nm.

FIG. 12 illustrates an electronic device D70 according to an embodiment.

The electronic device D70 illustrated in FIG. 12 may include a capacitor 1′ or a semiconductor device manufactured according to the method of etching a metal oxide layer by using ALE, illustrated in FIGS. 1 to 2D.

Referring to FIG. 12, the electronic device D70 may have a structure in which a plurality of capacitors 1′ and a plurality of field effect transistors are repeatedly arranged. The electronic device D70 may include a substrate 100′ including a source, a drain, and a channel, the field effect transistor including a gate stack 12, a contact structure 20′ arranged on the substrate 100′ so as not to overlap the gate stack 12, and the capacitor 1′ arranged on the contact structure 20′, and may further include a bit line structure 13 electrically connecting the plurality of field effect transistors to each other. Each of the plurality of capacitors 1′ may include the dielectric layer 300 and the insertion layer described above. Here, materials included in the dielectric layer 300 and the insertion layer are as described above.

FIG. 12 illustrates the semiconductor device D70 in which the contact structure 20′ and the capacitor 1′ are repeatedly arranged in an X direction and a Y direction, but an embodiment is not limited thereto. For example, the contact structure 20′ may be arranged in the X direction and the Y direction, and the capacitor 1′ may be arranged in a hexagonal shape, such as a honeycomb structure.

FIG. 13 is a cross-sectional view of the electronic device D70 taken along a line A-A′ of FIG. 12.

Referring to FIG. 13, the substrate 100′ may have a shallow trench isolation (STI) structure including a device isolation layer 14. The device isolation layer 14 may be a single layer including one type of insulating layer or a multi-layer including a combination of two or more types of insulating layers. The device isolation layer 14 may include a device isolation trench 14T in the substrate 100′ and the device isolation trench 14T may be filled with an insulating material. The insulating material may include at least one of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and tonen silazene (TOSZ).

The substrate 100′ may further include an active region AC defined by the device isolation layer 14 and a gate line trench 12T parallel to a top surface of the substrate 100′ and extending in the X direction. The active region AC may have a relatively long island shape having a minor axis and a major axis. The major axis of the active region AC may be arranged in a D3 direction parallel to the top surface of the substrate 100′, as shown in FIG. 13.

The gate line trench 12T may be arranged to cross the active region AC or inside the active region AC at a specific depth from the top surface of the substrate 100′. The gate line trench 12T may also be arranged inside the device isolation trench 14T, and the gate line trench 12T inside the device isolation trench 14T may have a lower bottom surface than the gate line trench 12T of the active region AC. A first source/drain 11′ab and a second source/drain 11″ab may be arranged at upper portions of the active region AC located on both sides of the gate line trench 12T.

The gate stack 12 may be arranged inside the gate line trench 12T. In detail, a gate insulating layer 12a, a gate electrode 12b, and a gate capping layer 12c may be sequentially arranged inside the gate line trench 12T. The gate insulating layer 12a and the gate electrode 12b may refer to the above description, and the gate capping layer 12c may include at least one of silicon oxide, silicon oxynitride, and silicon nitride. The gate capping layer 12c may be arranged on the gate electrode 12b to fill a remaining portion of the gate line trench 12T.

The bit line structure 13 may be arranged on the first source/drain 11′ab. The bit line structure 13 may be parallel to the top surface of the substrate 100′ and extend in the Y direction. The bit line structure 13 may be electrically connected to the first source/drain 11′ab and include, sequentially on the substrate 100′, a bit line contact 13a, a bit line 13b, and a bit line capping layer 13c. For example, the bit line contact 13a may include polysilicon, the bit line 13b may include a metal material, and the bit line capping layer 13c may include an insulating material, such as silicon nitride or silicon oxynitride.

In FIG. 13, the bit line contact 13a has a bottom surface on a same level as the top surface of the substrate 100′, but the bottom surface of the bit line contact 13a may be lower than the top surface of the substrate 100′ as the bit line contact 13a extends into a recess (not shown) formed at a certain depth from the top surface of the substrate 100′.

The bit line structure 13 may further include a bit line intermediate layer (not shown) between the bit line contact 13a and the bit line 13b. The bit line intermediate layer may include metal silicide, such as tungsten silicide, or metal nitride, such as tungsten nitride. Also, a bit line spacer (not shown) may be further formed on a side wall of the bit line structure 13. The bit line spacer may have a single layer structure or a multi-layer structure and may include an insulating material, such as silicon oxide, silicon oxynitride, or silicon nitride. Also, the bit line spacer may further include an air space (not shown).

The contact structure 20′ may be arranged on the second source/drain 11″ab. The contact structure 20′ and the bit line structure 13 may be arranged on different source/drain of the substrate. The contact structure 20′ may have a structure in which a lower contact pattern (not shown), a metal silicide layer (not shown), and an upper contact pattern (not shown) are sequentially stacked on the second source/drain 11″ab. The contact structure 20′ may further include a barrier layer (not shown) surrounding a side surface and a bottom surface of the upper contact pattern. For example, the lower contact pattern may include polysilicon, the upper contact pattern may include a metal material, and the barrier layer may include metal nitride having conductivity.

The capacitor 1′ may be electrically connected to the contact structure 20′ and arranged on the substrate 100′. In detail, the capacitor 1′ may include a lower electrode 151 electrically connected to the contact structure 20′, a dielectric layer 153 arranged on the lower electrode 151, and an upper electrode 152 arranged on the dielectric layer 153. The dielectric layer 153 may be arranged on the lower electrode 151 to be parallel to a surface of the lower electrode 151. The lower electrode 151, the dielectric layer 153, and the upper electrode 152 of the capacitor 1′ have been described above, and thus, descriptions thereof are omitted.

An interlayer insulating layer 15 may be further arranged between the capacitor 1′ and the substrate 100′. The interlayer insulating layer 15 may be arranged in a space between the capacitor 1′ and the substrate 100′, where another structure is not arranged. In detail, the interlayer insulating layer 15 may be arranged to cover structure of wires and/or the gate electrode 200, such as the bit line structure 13, the contact structure 20′, and the gate stack 12 on the substrate 100′. For example, the interlayer insulating layer 15 may surround a wall of the contact structure 20′. The interlayer insulating layer 15 may include a first interlayer insulating layer 15a surrounding the bit line contact 13a, and a second interlayer insulating layer 15b covering side surface sand/or top surfaces of the bit line 13b and bit line capping layer 13c.

The lower electrode 151 of the capacitor 1′ may be arranged on the interlayer insulating layer 15, specifically, on the second interlayer insulating layer 15b. Also, when a plurality of capacitors 1′ are arranged, bottom surfaces of a plurality of lower electrodes 151 may be isolated by an etch stop layer 16. In other words, the etch stop layer 16 may include an opening 16T and the bottom surface of the lower electrode 151 of the capacitor 1′ may be arranged in the opening 16T. The lower electrode 151 may have a cylinder shape or cup shape with a closed bottom, as shown in FIG. 13.

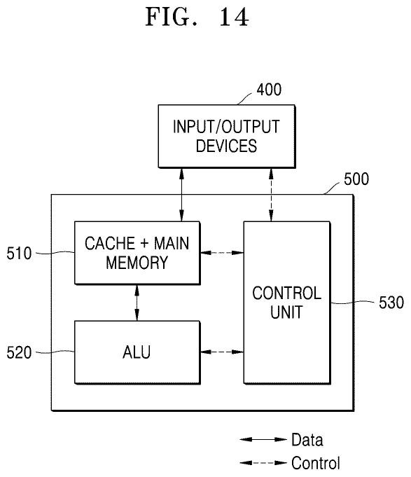

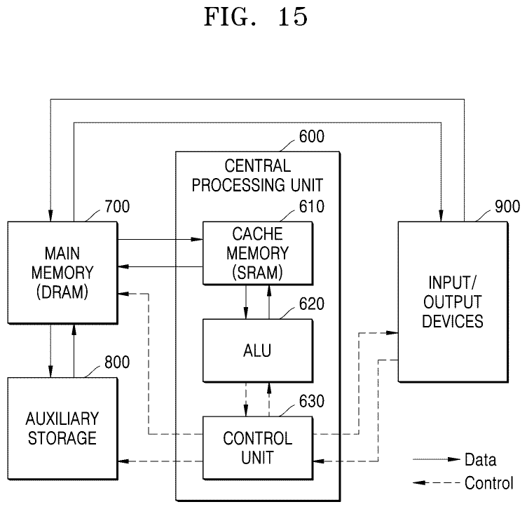

FIGS. 14 and 15 are conceptual diagrams schematically showing device architectures applicable to a device, according to an embodiment.

Referring to FIG. 14, an electronic device architecture 500 may include a memory unit 510, an arithmetic logic unit (ALU) 520, and a control unit 530. The memory unit 510, the ALU 520, and the control unit 530 may be electrically connected to each other. For example, the electronic device architecture 500 may be implemented as, for example, one chip including the memory unit 510, the ALU 520, and the control unit 530.

The memory unit 510, the ALU 520, and the control unit 530 may be connected to each other through a metal line on-chip and directly communicate with each other. The memory unit 510, the ALU 520, and the control unit 530 may configure one chip by being monolithically integrated on one substrate. The electronic device architecture 500 (chip) may be connected to input/output devices 400. The memory unit 510 may include both a main memory and a cache memory. Such an electronic device architecture 500 (chip) may be an on-chip memory processing unit. The memory unit 510, the ALU 520, and the control unit 530 may each include an electronic device described above.

Referring to FIG. 15, a cache memory 610, an ALU 620, and a control unit 630 may configure a central processing unit (CPU) 600, and the cache memory 610 may be static random-access memory (SRAM). A main memory 700 and an auxiliary storage 800 may be provided separately from the CPU 600. The main memory 700 may be DRAM and include the semiconductor device D10 described above. In some cases, an electronic device architecture may be implemented in the form in which computing unit devices and memory unit devices are adjacent to each other in one chip, without distinction of sub-units. Input/output devices (e.g., a keyboard, a display) may be connected to the control unit 630 of the CPU 600.

According to an embodiment, ALE is thermal ALE for precisely etching even a thin thickness without damaging a bottom substrate, by only using heat energy and precursors of two or more types, without the use of a plasma source.

However, effects of the disclosure are not limited thereto.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of etching a metal oxide layer by using atomic layer etching (ALE), the method comprising:
providing a first precursor including a fluorinated material to a target surface of the metal oxide layer;
forming a metal fluorinated layer, the forming the metal fluorinated layer including fluorinating the target surface of the metal oxide layer with the first precursor;
providing a second precursor including a metal halogenated material to the metal fluorinated layer; and
removing the metal fluorinated layer from the metal oxide layer by generating a volatile reactant from a reaction between the metal fluorinated layer and the metal halogenated material.

2. The method of claim 1, wherein the first precursor comprises one of molybdenum hexafluoride (MoF₆), hydrogen fluoride (HF), or HF-pyridine.

3. The method of claim 1, wherein the metal halogenated material comprises one of titanium tetrachloride (TiCl₄), sulfuryl chloride (SO₂Cl₂), or dimethylaluminum chloride ((CH₃)₂AlCl (DMAC)).

4. The method of claim 1, wherein the second precursor further comprises at least one of trimethylaluminum (Al(CH₃)₃ (TMA)), dimethylaluminum chloride ((CH₃)₂AlCl (DMAC)), acetylacetone (CH₃COCH₂COCH₃ (ACAC)), hexafluoroacetylacetone (CF₃COCH₂COCF₃ (HFAC)), silicon chloride (SiCl₄), or trimethylsilylchloride ((CH₃)₃SiCl).

5. The method of claim 1, further comprising:
purging the first precursor after the providing the first precursor or purging the second precursor after the providing the second precursor.

6. The method of claim 1, wherein a dielectric constant of the metal oxide layer is 10 or greater.

7. The method of claim 1, wherein the metal oxide layer comprises one of hafnium dioxide (HfO₂), zirconium dioxide (ZrO₂), aluminum oxide (Al₂O₃), tin dioxide (SnO₂), or titanium dioxide (TiO₂).

8. The method of claim 1, further comprising:
etching the target surface of the metal oxide layer, wherein
the etching the target surface of the metal oxide layer includes repeating the providing the first precursor and the providing of the second precursor for a plurality of cycles.

9. The method of claim 1, wherein the removing the metal fluorinated layer is performed through a thermal process at a temperature of 150° C. to 300° C.

10. The method of claim 1, wherein,
the metal oxide layer comprises at least one of hafnium dioxide (HfO₂), zirconium dioxide (ZrO₂), or titanium dioxide (TiO₂), and
the second precursor comprises at least one of titanium tetrachloride (TiCl₄), silicon chloride (SiCl₄), trimethylsilylchloride ((CH₃)₃SiCl), or sulfuryl chloride (SO₂Cl₂).

11. The method of claim 6, wherein a dielectric constant of the metal oxide layer is 20 or greater.

12. The method of claim 1, wherein a bandgap of the metal oxide layer is 3 to 8.

13. The method of claim 1, wherein an etch rate of the target surface is determined according to a type of the first precursor.

14. The method of claim 1, wherein the second precursor is in a gaseous state.

15. The method of claim 1, wherein a plasma gas is not provided during the providing the first precursor and the providing the second precursor.

16. The method of claim 8, wherein
during the etching the target surface of the metal oxide layer, an etch rate of the metal oxide layer is 2 Å/cycle or less.

17. The method of claim 1, wherein
a thickness of the target surface etched from the metal oxide layer is 0.01 nm to 0.1 nm.

18. A method of manufacturing a semiconductor device, the method comprising:
forming a metal oxide layer on a semiconductor layer;
providing a first precursor including a fluorinated material to a target surface of the metal oxide layer;
forming a metal fluorinated layer, the forming the metal fluorinate layer including fluorinating the target surface of the metal oxide layer with the first precursor;
providing a second precursor including a metal halogenated material to the metal fluorinated layer; and
removing the metal fluorinated layer from the metal oxide layer by generating a volatile reactant from a reaction between the metal fluorinated layer and the metal halogenated material.

19. The method of claim 18, wherein
the first precursor comprises one of molybdenum hexafluoride (MoF₆), hydrogen fluoride (HF), or HF-pyridine, and
the second precursor comprises one of titanium tetrachloride (TiCl₄), sulfuryl chloride (SO₂Cl₂), or dimethylaluminum chloride ((CH₃)₂AlCl (DMAC)).

20. The method of claim 18, wherein the metal oxide layer comprises one of hafnium dioxide (HfO₂), zirconium dioxide (ZrO₂), or titanium dioxide (TiO₂).
